(19) United States
(12) Patent Application Publication
(10) Pub. No.: US 2026/0358399 A1
(43) Pub. Date: Nov. 12, 2026

(54) SECONDARY BATTERY TESTING APPARATUS AND SECONDARY BATTERY TESTING METHOD

(71) Applicant: SK On Co., Ltd., Seoul (KR)

(72) Inventors: Won Je OH, Daejeon (KR); Jae Gyu BYUN, Daejeon (KR); Seung Won CHOI, Daejeon (KR)

(21) Appl. No.: 19/668,818

(22) Filed: May 6, 2026

(30) Foreign Application Priority Data
May 12, 2025 (KR) 10-2025-0060903

(51) Int. Cl. G01R 31/16; G01R 31/52

(52) U.S. Cl. CPC G01R 31/16; G01R 31/52

(57) ABSTRACT

Disclosed herein are a secondary battery testing apparatus and a secondary battery testing method. According to the present disclosure, there is provided the secondary battery testing apparatus including an outer case provided with an opening for receiving an electrode assembly, and an inner tube provided in a cylindrical shape, disposed inside the outer case, and expanding due to a working fluid supplied to an inner chamber to pressurize an outer surface of the electrode assembly.

### CROSS-REFERENCE TO RELATED APPLICATION

This application claims priority to and the benefit of Korean Patent Application No. 10-2025-0060903, filed on May 12, 2025, the disclosure of which is incorporated herein by reference in its entirety.

### TECHNICAL FIELD

The embodiments of the present disclosure relate to a secondary battery testing apparatus and a secondary battery testing method.

### BACKGROUND

Secondary batteries are energy storage devices that can be charged and discharged through electrochemical reactions. Secondary batteries are used in various fields using electric energy. For example, secondary batteries are widely used in mobile devices such as mobile phones, notebooks, and tablets, and their wider use is being sought in transportation such as cars, aircraft, and ships. In addition, the demand for secondary batteries is increasing in the field of energy storage systems (ESSs) for utilizing surplus power.

A secondary battery may be formed by alternately arranging positive electrodes and negative electrodes with separators interposed therebetween. For example, a cylindrical battery may be manufactured by winding positive electrodes and negative electrodes alternately disposed with separators interposed therebetween in a cylindrical shape to form an electrode assembly, and accommodating the electrode assembly inside a case. Meanwhile, the secondary battery may be processed through a plurality of process operations, and an external force applied in each process operation, various by-products generated during processing, and foreign materials introduced from the external environment may cause defects in the manufactured secondary battery. For example, the various by-products generated during the processing may be introduced into the electrode assembly and become factors that damage the separator and cause a short circuit. Therefore, it is necessary to properly determine whether the manufactured secondary battery is defective through the measurement of a leakage current, etc.

### SUMMARY

According to some embodiments of the present disclosure, a secondary battery testing apparatus and a secondary battery testing method may be provided.

In addition, according to some embodiments of the present disclosure, a secondary battery testing apparatus and a secondary battery testing method, which are capable of appropriately determining whether a processing defect of a secondary battery occurs, may be provided.

In addition, according to some embodiments of the present disclosure, a secondary battery testing apparatus and a secondary battery testing method, which are suitable for use in a cylindrical electrode assembly, may be provided.

In addition, according to some embodiments of the present disclosure, a secondary battery testing apparatus and a secondary battery testing method, which are capable of improving the reliability of test results, may be provided.

In addition, according to some embodiments of the present disclosure, a secondary battery testing apparatus and a secondary battery testing method, which are capable of preventing an electrode assembly from being damaged during a testing process, may be provided.

In addition, according to some embodiments of the present disclosure, a secondary battery testing apparatus and a secondary battery testing method, which are capable of improving a test speed, may be provided.

In addition, according to some embodiments of the present disclosure, a secondary battery testing apparatus and a secondary battery testing method, which are capable of easily applying various test conditions, may be provided.

Some embodiments of the present disclosure may be widely applied in green technology fields such as solar power generation and wind power generation using batteries in addition to electric vehicles and battery charging stations. In addition, some embodiments of the present disclosure may be used in eco-friendly electric vehicles, hybrid vehicles, etc., to prevent climate change by suppressing air pollution and greenhouse gas emissions.

According to an aspect of the present disclosure, there is provided a secondary battery testing apparatus that includes an outer case provided with an opening for receiving an electrode assembly, and an inner tube provided in a cylindrical shape, disposed inside the outer case, and expanding due to a working fluid supplied to an inner chamber to pressurize an outer surface of the electrode assembly.

In some embodiments, at least a portion of the outer case may be formed of a harder material than the inner tube to support expansion of the inner tube.

In some embodiments, the opening may be provided to receive the electrode assembly in a direction along a central shaft.

In some embodiments, the inner chamber may be provided to extend in a cylindrical shape inside the inner tube.

In some embodiments, the inner tube may include an inner surface extending to surround an accommodation space, in which the electrode assembly is disposed, in a circumferential direction, and the inner surface may come into contact with and pressurize the outer surface of the electrode assembly while the working fluid is supplied.

In some embodiments, the inner tube may be provided such that an outer surface of the inner tube expands while supported on an inner surface of the outer case, and an inner surface of the inner tube pressurizes the outer surface of the electrode assembly.

In some embodiments, a material of the inner tube may include at least one of butyl rubber, ethylene propylene diene monomer (EPDM) rubber, Kevlar, and a polyethylene resin.

In some embodiments, the inner tube may include an injection hole connected to a supply unit for the working fluid and configured to guide the working fluid to be supplied from the supply unit to the inner chamber.

In some embodiments, the secondary battery testing apparatus may further include measurement terminals electrically connected to electrodes of the electrode assembly and configured to apply a test voltage to the electrode assembly in a state in which the electrode assembly is pressurized.

In some embodiments, the measurement terminals may include a first measurement terminal electrically connected to a first surface of the electrode assembly through the opening, and a second measurement terminal disposed inside the outer case and electrically connected to a second surface of the electrode assembly.

In some embodiments, the secondary battery testing apparatus may further include a detector configured to measure at least one of a leakage current and an insulation resistance between the measurement terminals while the test voltage is applied.

In some embodiments, the secondary battery testing apparatus may further include a stage disposed inside the inner tube to allow the electrode assembly to be seated and provided to be movable in input and discharge directions of the electrode assembly.

In some embodiments, the stage may include a core pin inserted into and fastened in a winding hole provided in the central shaft of the electrode assembly when the electrode assembly is seated.

According to another aspect of the present disclosure, there is provided a secondary battery testing method that includes inserting a cylindrical electrode assembly into an accommodation space inside an inner tube, supplying a working fluid to the inner tube and pressurizing an outer surface of the electrode assembly by an inner surface of the inner tube, and applying a test voltage to each electrode of the electrode assembly, and measuring at least one of a leakage current and an insulation resistance between measurement terminals while the test voltage is applied.

In some embodiments, the secondary battery testing method may further include discharging at least a portion of the working fluid from the inner tube, and releasing a pressure applied to the outer surface of the electrode assembly, and separating the electrode assembly from the inner tube.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is an exemplary diagram illustrating an electrode assembly of a secondary battery;

FIG. 2 is a perspective view illustrating a secondary battery testing apparatus according to one embodiment of the present disclosure;

FIG. 3 is an exploded perspective view of the testing apparatus shown in FIG. 2;

FIG. 4 is a cross-sectional view of the testing apparatus shown in FIG. 2;

FIG. 5 is a plan view of the testing apparatus shown in FIG. 2;

FIG. 6 is an exemplary diagram of an operation of the testing apparatus shown in FIG. 2;

FIG. 7 is a perspective view illustrating a secondary battery testing apparatus according to another embodiment of the present disclosure;

FIG. 8 is a cross-sectional view of the testing apparatus shown in FIG. 7;

FIG. 9 is a diagram illustrating a first operating state of the testing apparatus shown in FIG. 7;

FIG. 10 is a diagram illustrating a second operating state of the testing apparatus shown in FIG. 7;

FIG. 11 is a diagram illustrating a third operating state of the testing apparatus shown in FIG. 7; and

FIG. 12 is a flowchart illustrating a secondary battery testing method according to one embodiment of the present disclosure.

### DETAILED DESCRIPTION

Hereinafter, the present disclosure will be described in detail with reference to the accompanying drawings. However, this is merely exemplary, and the present disclosure is not limited to specific embodiments described as examples.

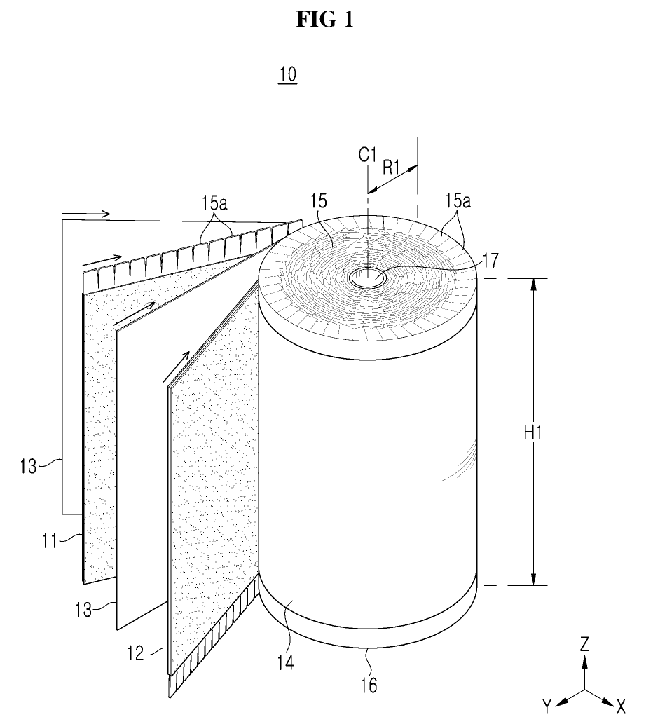

FIG. 1 is an exemplary diagram illustrating an electrode assembly of a secondary battery.

Hereinafter, an x-axis direction is referred to as a left-right direction, a y-axis direction is referred to as a front-rear direction, and a z-axis direction is referred to as an up-down direction based on coordinate axes shown in FIG. 1 and the like. In addition, a rotation direction around a central shaft C1 is referred to as a circumferential direction, and a direction extending from the central shaft C1 to an xy-plane is referred to as a radius direction based on the central shaft C1 in the z-axis direction.

FIG. 1 shows one electrode assembly 10 of a secondary battery. In some embodiments, the electrode assembly 10 may be provided in a cylindrical shape. For example, the electrode assembly 10 may be provided by winding a first electrode 11 and a second electrode 12 disposed alternately with a separator 13 interposed therebetween in a cylindrical shape around the central shaft C1.

In some embodiments, the secondary battery testing apparatus (hereinafter referred to as a “testing apparatus 100”), which will be described below, may be applied to the cylindrical electrode assembly 10 as shown in the drawing. In other words, the testing apparatus 100 may be appropriately used to measure a leakage current and the like of the cylindrical electrode assembly 10. In addition, the testing apparatus 100 may be provided to uniformly pressurize an outer surface 14 of the cylindrical electrode assembly 10 and measure a leakage current and the like of the electrode assembly 10 while the electrode assembly 10 is pressurized. The testing apparatus 100 may function to more clearly identify whether there are processing defects in the cylindrical electrode assembly 10. For example, the testing apparatus 100 may amplify an influence of foreign materials through appropriate pressurization and measure a leakage current, etc., under such conditions to more clearly identify whether there are processing defects.

However, an application target of the testing apparatus 100 is not necessarily limited to the exemplified cylindrical electrode assembly 10. The testing apparatus 100 may be applied to or utilized for the electrode assembly 10 having a form different from that of the exemplified electrode assembly 10, within the scope appropriately including the technical concept which will be described below.

Meanwhile, the cylindrical electrode assembly 10 may have a predetermined radius R1 and a predetermined height H1. In the illustrated embodiment, the radius R1 of the electrode assembly 10 may be a length from the central shaft C1 to the outer surface 14 of the electrode assembly 10 on the xy plane. In addition, a height H1 of the electrode assembly 10 may be a length of the electrode assembly 10 in the z-axis direction. In the present disclosure, the radius R1 and the height H1 of the electrode assembly 10 to which the testing apparatus 100 is applied are not particularly limited. In addition, in some embodiments, the testing apparatus 100 may be provided to be applicable to electrode assemblies 10 having different specifications. In other words, the testing apparatus 100 may be provided to be compatible with the electrode assemblies 10 having different specifications in which some radii R1 and/or heights H1 differ. Such a testing apparatus 100 may contribute to improving convenience in use and efficiency of equipment operation.

In some embodiments, the cylindrical electrode assembly 10 may have a first surface 15 and a second surface 16. The first surface 15 and the second surface 16 may be disposed to be spaced apart at predetermined intervals in an axial direction of the central shaft C1. In the illustrated embodiment, the first surface 15 may correspond to a top surface of the electrode assembly 10, and the second surface 16 may correspond to a bottom surface of the electrode assembly 10. In some embodiments, a plurality of first fragments 15a extending from the first electrode 11 may be disposed on the first surface 15. For example, the first surface 15 may be provided as a schematic surface formed by folding the plurality of first fragments 15a toward the central shaft C1. Similarly, a plurality of second fragments (not shown) extending from the second electrode 12 may be disposed on the second surface 16. For example, the second surface 16 may be provided as a schematic surface formed by folding the plurality of second fragments toward the central shaft C1.

In the above description, the first surface 15 of the electrode assembly 10 may function as one connection surface that is electrically connected to a first electrode terminal (not shown). Similarly, the second surface 16 of the electrode assembly 10 may function as another connection surface that is electrically connected to a second electrode terminal (not shown). For example, the first surface 15 of the electrode assembly 10 may be electrically connected to a positive electrode terminal through an electrical connector such as one current collector, and the second surface 16 of the electrode assembly 10 may be electrically connected to a negative electrode terminal through an electrical connector such as another current collector.

Meanwhile, in some embodiments, the cylindrical electrode assembly 10 may be provided with the outer surface 14. The outer surface 14 may extend between the first surface 15 and the second surface 16 in a circumferential direction. In the illustrated embodiment, the outer surface 14 may be provided to form a lateral perimeter of the electrode assembly 10. According to the shape of the cylindrical electrode assembly 10, the outer surface 14 may extend in a curved shape with a predetermined curvature based on the central shaft C1.

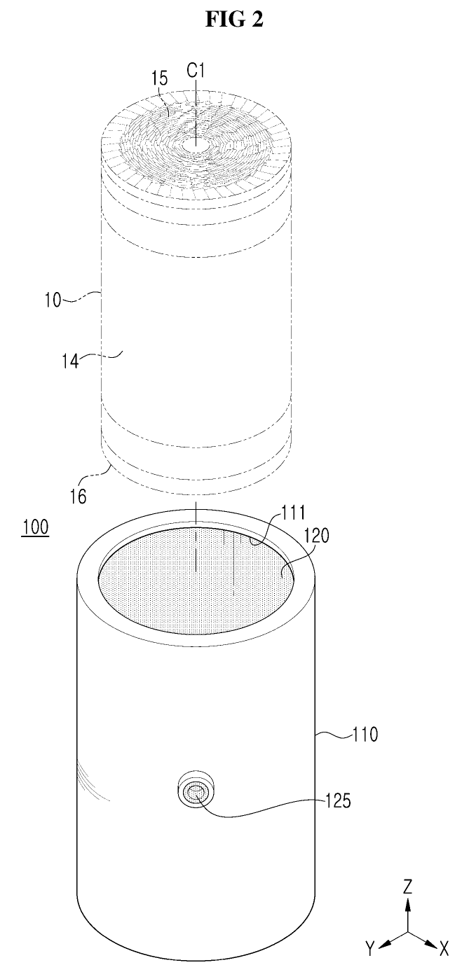

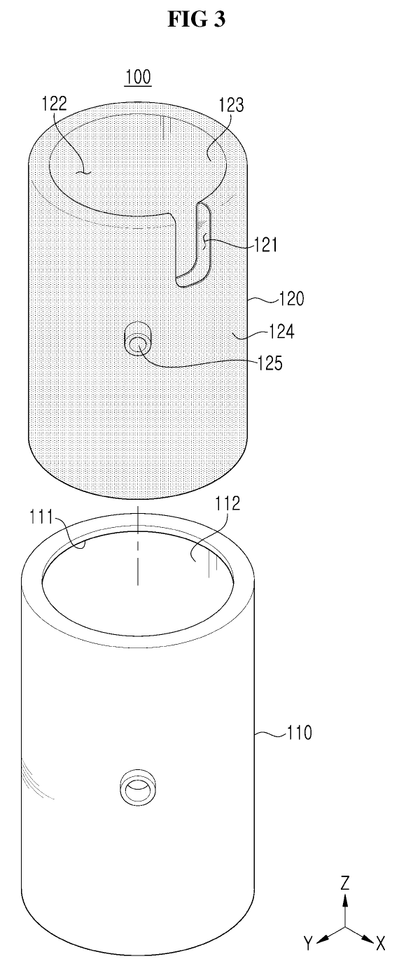

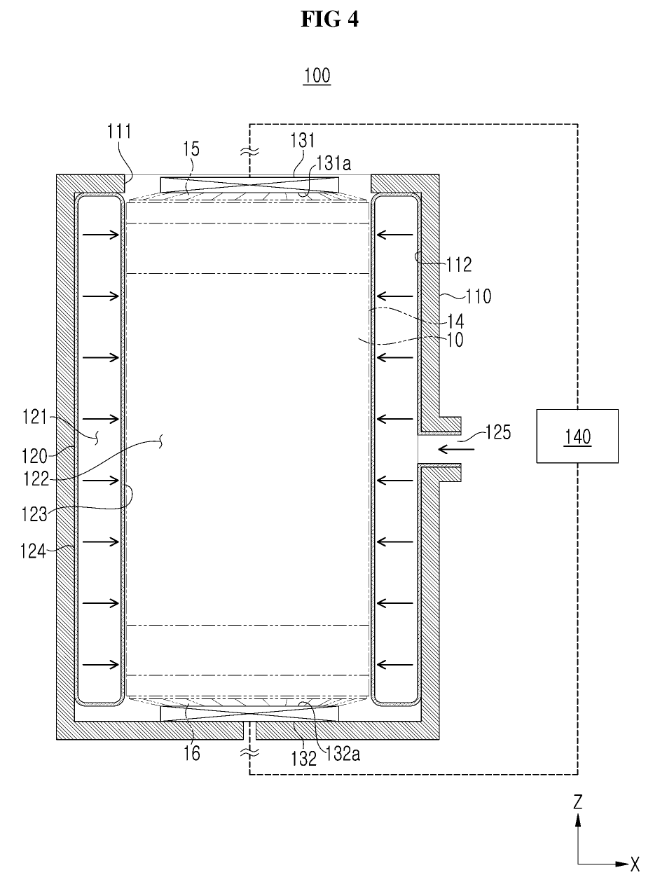

FIG. 2 is a perspective view illustrating a secondary battery testing apparatus according to one embodiment of the present disclosure. FIG. 3 is an exploded perspective view of the testing apparatus shown in FIG. 2. FIG. 4 is a cross-sectional view of the testing apparatus shown in FIG. 2. FIG. 5 is a plan view of the testing apparatus shown in FIG. 2.

Referring to FIGS. 2 - 5, in some embodiments, the testing apparatus 100 may be provided. The testing apparatus 100 may be used to measure a leakage current and the like of the above-described electrode assembly 10. In some embodiments, the testing apparatus 100 may include an outer case 110 provided with an opening 111 for inputting the electrode assembly 10, and an inner tube 120 provided in a cylindrical shape, disposed inside the outer case 110, and expanded by a working fluid supplied to an inner chamber 121 to pressurize the outer surface 14 of the electrode assembly 10.

Specifically, the testing apparatus 100 may include the outer case 110. The outer case 110 may be provided with the opening 111 for inputting the electrode assembly 10. In the illustrated embodiment, the outer case 110 is illustrated as having a substantially cylindrical shape and being provided with the opening 111 at an upper end. However, the exterior shape of the outer case 110 may be modified as necessary and is not necessarily limited to the illustrated embodiment.

In some embodiments, the opening 111 may be provided such that the electrode assembly 10 is input in an axial direction of the central shaft C1. In other words, the opening 111 may be provided to open in a direction corresponding to the central shaft C1 of the electrode assembly 10. For example, in the illustrated embodiment, the electrode assembly 10 may be provided such that the central shaft C1 is disposed in the up-down direction, and the opening 111 may open toward an upper side. In addition, the electrode assembly 10 may be moved downward toward the opening 111 while waiting on the upper side of the opening 111 and input inside the outer case 110. This input method of the electrode assembly 10 may contribute to rapid input and discharge of the electrode assembly 10 by the testing apparatus 100.

In some embodiments, the outer case 110 may include an inner surface 112 disposed to face an inner tube 120 which will be described below. The inner surface 112 of the outer case 110 may be formed to extend in a cylindrical shape to correspond to an outer surface 124 of the inner tube 120. The inner surface 112 of the outer case 110, which extends in a cylindrical shape as described above, may uniformly come into contact with and support an outer surface 124 of the inner tube 120 as the inner tube 120 expands, thereby contributing to transmission of a uniform pressure to the electrode assembly 10.

Meanwhile, in some embodiments, the outer case 110 may be formed of a harder material than the inner tube 120. In other words, the inner tube 120 is formed with a flexible material capable of elastic deformation, whereas the outer case 110 may be formed with a rigid material capable of adequately supporting the elastic deformation of the inner tube 120. For example, a material of the outer case 110 may include a metal or plastic that can maintain its shape against a predetermined test pressure. The outer case 110 supports the outer surface 124 of the inner tube 120 in response to the expansion of the inner tube 120 and allows the electrode assembly 10 to be properly pressurized by the inner tube 120.

In some embodiments, the outer case 110 may include an electrically insulating material. For example, the outer case 110 may be formed with an integral plastic material having electrical insulation properties. Alternatively, electrically insulating coating may be performed on an outer surface of the outer case 110. Alternatively, in the outer case 110, a portion including an area of the inner surface 112 in which the inner tube 120, which will be described below, is disposed may be partially formed with an electrically insulating material.

Meanwhile, in some embodiments, the testing apparatus 100 may include the inner tube 120. The inner tube 120 is provided in a cylindrical shape and may be disposed inside the outer case 110. For example, in the illustrated embodiment, the outer case 110 may be provided in a cylindrical shape that is slightly greater than the inner tube 120, and the inner tube 120 may be provided in a cylindrical shape that is disposed inside the outer case 110. In addition, the inner tube 120 may be disposed such that the outer surface 124 faces the inner surface 112 of the outer case 110.

In some embodiments, the inner tube 120 may be provided with the inner chamber 121. The inner chamber 121 may be provided as a predetermined space that is provided inside the inner tube 120. For reference, FIG. 3 shows the inner chamber 121 by cutting a portion of an upper end of the inner tube 120. The inner tube 120 may expand to supply a working fluid to the inner chamber 121 or contract to discharge the working fluid from the inner chamber 121.

In some embodiments, the inner chamber 121 may be provided to extend in a cylindrical shape inside the inner tube 120. For example, the inner tube 120 may be provided by forming an elastic sheet member that is bonded in two layers into a cylindrical shape, and the inner chamber 121 that extends in a cylindrical shape may be provided inside the inner tube 120. The cylindrical inner chamber 121 may function to uniformly pressurize the outer surface 14 of the electrode assembly 10 while the working fluid is supplied.

Meanwhile, in some embodiments, the inner tube 120 may be provided with an accommodation space 122 in which the electrode assembly 10 is disposed. The accommodation space 122 may be provided as a predetermined space surrounded by the cylindrical inner tube 120. In addition, the inner tube 120 may include an inner surface 123 that extends to surround the accommodation space 122 in a circumferential direction. The inner surface 123 of the inner tube 120 may be formed come into contact with and pressurize the outer surface 14 of the electrode assembly 10 according to the supply of the working fluid. In other words, the inner tube 120 may expand in a thickness direction according to the supply of the working fluid, and thus the inner surface 123 of the inner tube 120 may come into contact with and pressurize the outer surface 14 of the electrode assembly 10. For reference, the thickness direction may be the radius direction based on the central shaft C1.

In some embodiments, the inner tube 120 may be provided to be elastically deformable in the thickness direction. In other words, the inner tube 120 may be provided to expand or contract in the thickness direction. The inner tube 120 may be provided to expand while the outer surface 124 is supported by the inner surface 112 of the outer case 110, thereby pressurizing the outer surface 14 of the electrode assembly 10. In other words, the inner tube 120 may be provided to expand in the thickness direction so that the inner surface 123 pressurizes the outer surface 14 of the electrode assembly 10.

In some embodiments, the inner tube 120 may be provided to expand or contract due to the working fluid. In other words, the inner tube 120 may be provided to expand while the working fluid is supplied to the inner chamber 121 or to contract while the working fluid flows out of the inner chamber 121. In this way, the method in which the inner tube 120 expands or contracts using the working fluid may contribute to rapidly and uniformly pressurizing the outer surface 14 of the electrode assembly 10 through the inner tube 120.

In the above description, the inner tube 120 may be provided with an injection hole 125 for supplying and discharging the working fluid. The injection hole 125 may be provided to be connected to the inner chamber 121 to guide the supply and discharge of the working fluid to and from the inner chamber 121. Although not shown in the drawings, the injection hole 125 may be connected to a supply unit that supplies the working fluid. For example, the supply unit may include a pump, actuator, etc., that use a fluid as a medium.

In the illustrated embodiment, the injection hole 125 as described above may be located in a central portion of the inner tube 120 in the up-down direction. In addition, while the inner tube 120 is disposed inside the outer case 110, the injection hole 125 may be provided to be appropriately exposed to the outside of the outer case 110. However, the position, number, etc., of the injection hole 125 may be appropriately changed as necessary and are not necessarily limited to the illustrated embodiment.

Meanwhile, in some embodiments, the inner tube 120 may include an elastic material. In other words, at least a portion of the inner tube 120 may include an elastic material to be elastically deformed according to the supply or discharge of the working fluid. For example, the inner tube 120 may be provided by molding an integral elastic material into a tube shape.

In the above description, the material of the inner tube 120 may be selected from materials with good elasticity, good pressure resistance, etc. For example, the material of the inner tube 120 may include rubber, silicone, a synthetic resin, etc. More specifically, the material of the inner tube 120 may include butyl rubber, an ethylene propylene diene monomer (EPDM), rubber, Kevlar, a polyethylene resin, etc. The exemplified butyl rubber and EPDM rubber may be more suitably selected when a gas (air) is used as the working fluid. In addition, the exemplified Kevlar and polyethylene resin may have advantages of pressure resistance, durability, etc.

In addition, the inner tube 120 may include an electrically insulating material. For example, the material of the inner tube 120 may include the butyl rubber, EPDM rubber, Kevlar, polyethylene resin, etc., and to have electrical insulation properties.

Meanwhile, the working fluid may be provided as a gas or a liquid. In other words, in the present description, “fluid” may be used to encompass a gas and a liquid. For example, the working fluid may be provided as a gas such as air or provided as a liquid such as insulating oil. However, a type of the working fluid is not particularly limited as long as it has a certain fluidity and may be supplied and discharged inside and outside the inner chamber 121.

Meanwhile, in some embodiments, the testing apparatus 100 may further include measurement terminals 131 and 132 that apply test voltages to the electrode assembly 10. For reference, the measurement terminals 131 and 132 are shown in FIG. 4 and are omitted in FIGS. 2 and 3. The measurement terminals 131 and 132 may be provided to be electrically connected to the electrodes 11 and 12 of the electrode assembly 10, respectively. In addition, the measurement terminals 131 and 132 may be provided to apply test voltages through the electrodes 11 and 12 while the electrode assembly 10 is pressurized. Accordingly, the testing apparatus 100 may be provided to inspect whether a leakage current occurs between the electrodes 11 and 12.

In some embodiments, the measurement terminals 131 and 132 may include a first measurement terminal 131 electrically connected to the first electrode 11 of the electrode assembly 10, and a second measurement terminal 132 electrically connected to the second electrode 12 of the electrode assembly 10. In the illustrated embodiment, the first measurement terminal 131 may be provided to be disposed on the first surface 15 of the electrode assembly 10 and to be electrically connected to the plurality of first fragments 15a provided on the first surface 15. In addition, the first measurement terminal 131 may be provided to include an electrically conductive material and to be in contact with the first surface 15 of the electrode assembly 10, thereby being electrically connected to the first electrode 11. In addition, the first measurement terminal 131 may be provided to approach the first surface 15 of the electrode assembly 10 through the opening 111 disposed on the upper end of the testing apparatus 100.

Similarly to the above description, in the illustrated embodiment, the second measurement terminal 132 may be provided to be disposed on the second surface 16 of the electrode assembly 10, thereby being electrically connected to the plurality of second fragments provided on the second surface 16. In addition, the second measurement terminal 132 may be provided to include an electrically conductive material and to be in contact with the second surface 16 of the electrode assembly 10, thereby being electrically connected to the second electrode 12. Meanwhile, in the illustrated embodiment, the second measurement terminal 132 may be disposed inside the outer case 110. In other words, since the second measurement terminal 132 is disposed on an inner bottom surface of the outer case 110 and the electrode assembly 10 is seated inside the outer case 110, the second measurement terminal 132 may be provided to be electrically connected to the second electrode 12.

In some embodiments, the first and second measurement terminals 131 and 132 may include contact surfaces 131aand 132ain contact with the first surface 15 and the second surface 16 of the electrode assembly 10. To describe the first measurement terminal 131 as an example, the first measurement terminal 131 may be provided with the contact surface 131aon a bottom surface disposed toward the electrode assembly 10, and the contact surface 131a may be provided to come into contact with the first surface 15 of the electrode assembly 10 according to movement of the first measurement terminal 131, thereby being electrically connected to the first electrode 11.

In some embodiments, each of the contact surfaces 131a and 132a may be provided in a planar shape. For example, in the illustrated embodiment, each of the contact surfaces 131a and 132a may be provided in a planar shape having a predetermined area on the xy plane. In addition, the contact surface 131a may be provided in a circular planar shape that may be disposed in an inner area of the first surface 15 on the xy plane. The planar-shaped contact surfaces 131aand 132a may contribute to properly securing electrical connection paths for applying test voltages without damaging the first and second fragments provided in the electrode assembly 10.

Meanwhile, in some embodiments, the testing apparatus 100 may further include a detector 140. For reference, the detector 140 is shown in FIG. 4 and is omitted in FIGS. 2 and 3. The detector 140 may be provided to measure a leakage current or insulation resistance between the measurement terminals 131 and 132 while the test voltage is applied. In addition, the detector 140 may be provided to detect whether an insulation failure of the electrode assembly 10 occurs by comparing the measured leakage current with a preset reference value. In some embodiments, the detector 140 may include an ammeter, a voltmeter, etc.

To describe an operation of the testing apparatus 100, first, the cylindrical electrode assembly 10 may be input into the accommodation space 122 inside the inner tube 120. In addition, the first and second measurement terminals 131 and 132 may be electrically connected to the electrode assembly 10. In the illustrated embodiment, as the electrode assembly 10 is inserted into the inner tube 120, the second measurement terminal 132 may be in contact with the second surface 16 of the electrode assembly 10 to be electrically connected to the second electrode 12. In addition, after the electrode assembly 10 is input, the first measurement terminal 131 may be in contact with the first surface 15 of the electrode assembly 10 through the opening 111 to be electrically connected to the first electrode 11.

Next, the working fluid may be supplied to the inner chamber 121 of the inner tube 120. Accordingly, the inner tube 120 may expand to a certain extent between the inner surface 112 of the outer case 110 and the outer surface 14 of the electrode assembly 10. In addition, the outer surface 14 of the electrode assembly 10 may be pressurized by the inner surface 123 of the inner tube 120.

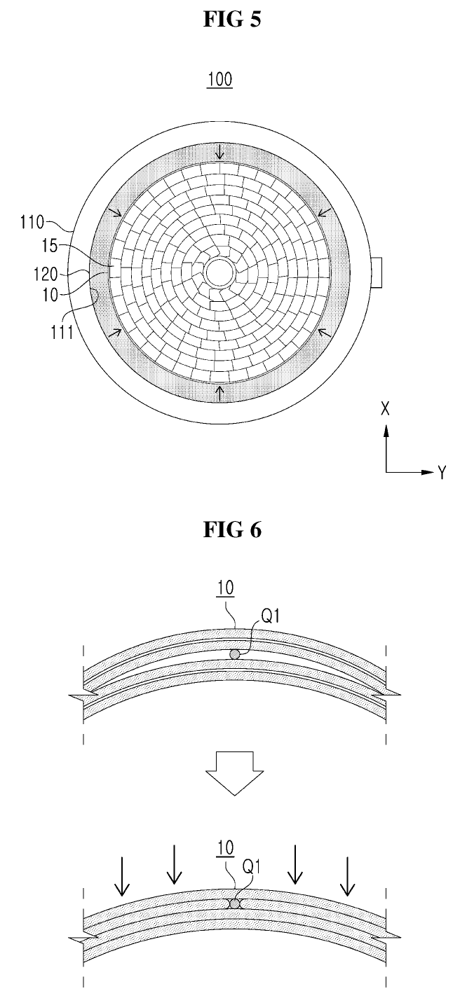

FIG. 6 is an exemplary diagram of an operation of the testing apparatus shown in FIG. 2.

Referring to FIG. 6, the pressurization of the electrode assembly 10 as described above may contribute to more completely detecting foreign materials remaining inside the electrode assembly 10. For example, as shown in the drawing, a foreign material Q1 remaining inside the electrode assembly 10 has a limited influence on the electrode, separator, etc., before a pressurized state, but after being appropriately pressurized, the influence may be amplified, such as causing damage to the electrode, separator, etc. Accordingly, the foreign material Q1 may be detected more completely through measurement of the leakage current, insulation resistance, etc., in the pressurized state.

Referring to FIGS. 2 -5 again, test voltages may be applied to the electrode assembly 10. For example, the first and second measurement terminals 131 and 132 may be electrically connected to the first and second surfaces 15 and 16 of the electrode assembly 10, respectively, and predetermined test voltages may be applied to the first and second measurement terminals 131 and 132. In addition, when the test voltage is applied, the detector 140 may measure a leakage current or insulation resistance between the first and second measurement terminals 131 and 132. In addition, in this way, the detector 140 may detect whether an insulation failure of the electrode assembly 10 occurs.

Meanwhile, when the measurement of the leakage current, etc., as described above is completed, the electrode assembly 10 may be separated again from the testing apparatus 100. For example, the working fluid is discharged from the inner tube 120 so that the pressure applied to the outer surface 14 of the electrode assembly 10 is released. In addition, accordingly, the electrode assembly 10 may be switched to a state of being separable from the testing apparatus 100 and may be separated from the testing apparatus 100 through the upper opening 111.

Although not shown in the drawings, in some other embodiments, the electrode assembly 10 may be separated in a direction different from the input direction. For example, the outer case 110 may be provided in a structure having openings on the upper and lower sides, and the electrode assembly 10 may be provided to be input into the testing apparatus 100 through the upper side of the outer case 110 and to be discharged from the testing apparatus 100 through the lower side of the outer case 110.

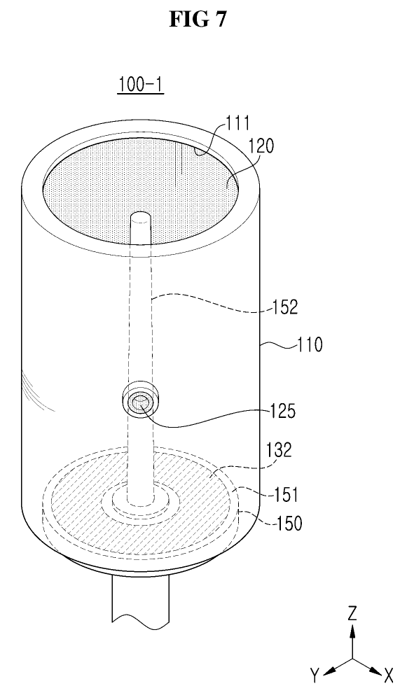

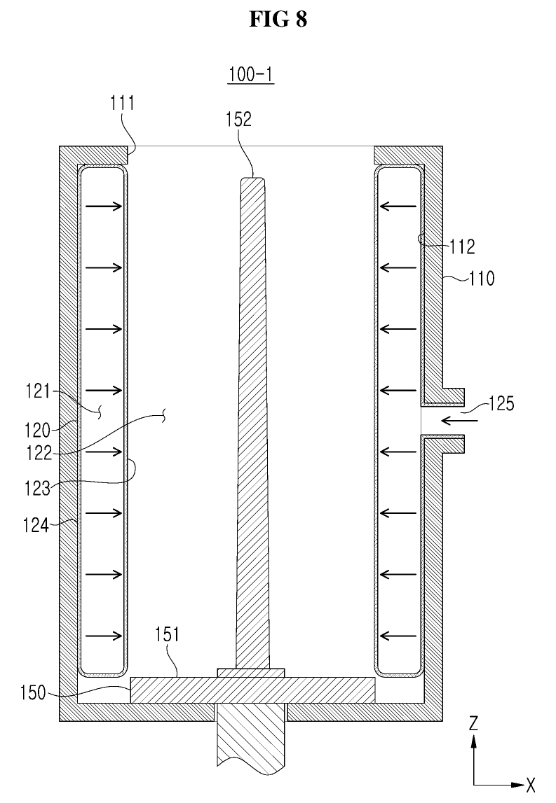

FIG. 7 is a perspective view illustrating a secondary battery testing apparatus according to another embodiment of the present disclosure. FIG. 8 is a cross-sectional view of the testing apparatus shown in FIG. 7.

For convenience, hereinafter, a difference from the above embodiment will be mainly described.

Referring to FIGS. 7 and 8, in some embodiments, a testing apparatus 100-1 may further include a stage 150. The stage 150 may be provided with a seating surface 151 on which an electrode assembly 10 may be seated and may be disposed inside an inner tube 120. In other words, the stage 150 may be disposed in an accommodation space 122 of the inner tube 120. In addition, the stage 150 may be provided to be movable in input and output directions of the electrode assembly 10. For example, in the illustrated embodiment, the electrode assembly 10 may be provided to be input and discharged in the up-down direction, and thus the stage 150 may be provided to be movable inside the inner tube 120 in the up-down direction.

In some embodiments, the stage 150 may include a core pin 152. In the illustrated embodiment, the core pin 152 may be disposed at the center of a seating surface 151 of the stage 150 to be formed to extend in the up-down direction. The core pin 152 may be provided to be inserted into and fastened in the winding hole 17 (see FIG. 1) provided in the central shaft C1 of the electrode assembly 10. In other words, the core pin 152 may be provided to be inserted into and fastened in the winding hole 17 when the electrode assembly 10 is seated on the stage 150 and to be detached from the winding hole 17 when the electrode assembly 10 is separated from the stage 150.

In some embodiments, each of the stage 150 and the core pin 152 may include an electrically insulating material. For example, the entirety of each of the stage 150 and the core pin 152 may be formed of an electrically insulating material, or electrically insulating coating is performed on an area thereof in contact with the electrode assembly 10.

Meanwhile, in some embodiments, a second measurement terminal 132 may be provided on the seating surface 151 of the stage 150. For example, as shown in the drawing, the second measurement terminal 132 may be formed to extend in a circular ring shape based on the core pin 152 on the seating surface 151. As the electrode assembly 10 is seated on the stage 150, the second measurement terminal 132 may be in contact with the second surface 16 of the electrode assembly 10 to be electrically connected thereto.

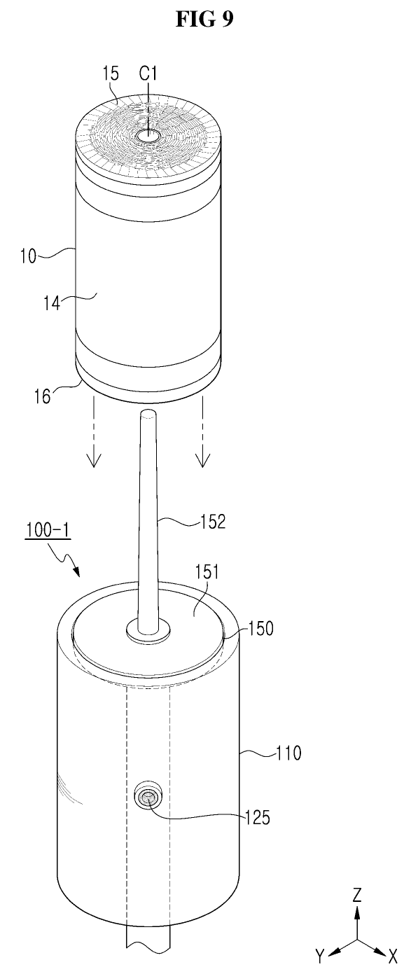

FIG. 9 is a diagram illustrating a first operating state of the testing apparatus shown in FIG. 7.

Referring to FIG. 9, in the testing apparatus 100-1, the stage 150 may move up for the inputting of the electrode assembly 10. For example, in the illustrated operation example, the stage 150 may move up to a position corresponding to the upper end of the outer case 110 to be exposed through the opening 111. In addition, as described above, in the state in which the stage 150 has moved up, the electrode assembly 10 may be supplied to the stage 150. In a state in which the central shaft C1 is aligned with the core pin 152, the electrode assembly 10 may move down toward the stage 150 to be supplied to the stage 150.

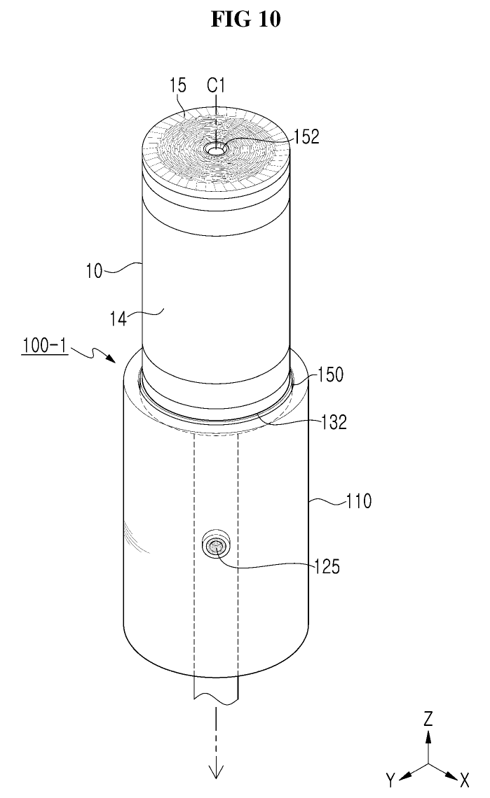

FIG. 10 is a diagram illustrating a second operating state of the testing apparatus shown in FIG. 7.

Referring to FIG. 10, as the core pin 152 is inserted into the winding hole 17 corresponding to the central shaft C1, the electrode assembly 10 may be seated on the seating surface 151 of the stage 150. The core pin 152 may function to guide coupling between the electrode assembly 10 and the stage 150. In other words, as the core pin 152 is inserted into the winding hole 17, the electrode assembly 10 may be disposed in a state of being aligned with the center of the stage 150. Accordingly, during a subsequent test process, a pressurizing force from the inner tube 120 may be applied uniformly to the outer surface 14 of the electrode assembly 10.

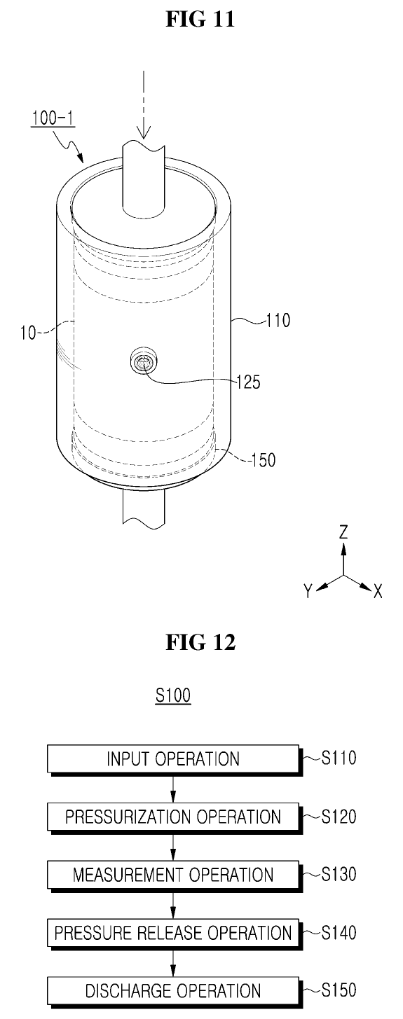

FIG. 11 is a diagram illustrating a third operating state of the testing apparatus shown in FIG. 7.

Referring to FIG. 11, subsequently, the stage 150 may move down. As the stage 150 moves down, the electrode assembly 10 may be disposed inside the inner tube 120. In addition, the first measurement terminal 131 may be in contact with the first surface 15 of the electrode assembly 10 to be electrically connected thereto. Next, predetermined test voltages are applied to the first and second measurement terminals 131 and 132, and thus measurement of the leakage current, etc., may be performed. Meanwhile, when the measurement is completed, the stage 150 may move up again, and the electrode assembly 10 may be separated from the core pin 152.

The stage 150 may move inside and outside of the inner tube 120 to function to assist with the input and discharge of the electrode assembly 10. Accordingly, test convenience can be further improved, and a test time can be further shortened. In addition, the core pin 152 provided at the stage 150 may be inserted into the winding hole 17 in the center of the electrode assembly 10 to align the position of the electrode assembly 10 and contribute to implementing a more stable support state. In addition, when the electrode assembly 10 is pressurized, the core pin 152 may properly maintain the position of the electrode assembly 10 to contribute to applying a uniform pressure to the outer surface 14 of the electrode assembly 10. In addition, when the electrode assembly 10 is pressurized, the core pin 152 may function to prevent the winding hole 17 from being deformed.

FIG. 12 is a flowchart illustrating a secondary battery testing method according to one embodiment of the present disclosure.

Referring to FIG. 12, according to another aspect of the present disclosure, a testing method S100 of measuring a leakage current of a secondary battery may be provided. In some embodiments, the testing method S100 may be performed through the testing apparatuses 100 and 100-1 of the above-described embodiments. However, the present disclosure is not necessarily limited thereto, and in some cases, the testing method S100 may be implemented through an apparatus different from the above-described testing apparatuses 100 and 100-1.

In some embodiments, the testing method S100 may include inserting the cylindrical electrode assembly 10 into the accommodation space 122 inside the inner tube 120 (S110), supplying a working fluid to the inner tube 120 to pressurize the outer surface 14 of the electrode assembly 10 by the inner surface 123 of the inner tube 120 (S120), and applying a test voltage to each of the electrodes 11 and 12 of the electrode assembly 10 and measuring at least one of a leakage current and an insulation resistance between the measurement terminals 131 and 132 while the test voltage is applied (S130).

In addition, in some embodiments, the testing method S100 may further include discharging at least a portion of a working fluid from the inner tube 120 and releasing a pressure applied to the outer surface 14 of the electrode assembly 10 (S140), and separating the electrode assembly 10 from the inner tube 120 (S150).

The inserting step S110, the pressurization step S120, the measurement step S130, the pressure release step S140, and the separating step S150 may be performed similarly to those described above through FIGS. 1 - 6. Alternatively, the inserting step S110, the pressurization step S120, the measurement step S130, the pressure release step S140, and the separating step S150 may be performed similarly to those described above through FIGS. 9 - 11.

As described above, according to some embodiments of the present disclosure, the secondary battery testing apparatus and the secondary battery testing method may be provided.

In addition, according to some embodiments of the present disclosure, a secondary battery testing apparatus and a secondary battery testing method may be provided, which are capable of appropriately determining whether a processing defect of a secondary battery occurs. In some embodiments, the testing apparatus may be provided such that the inner tube expands and pressurizes the outer surface of the electrode assembly while the working fluid is supplied, and thus a leakage current of the electrode assembly may be measured while an influence due to internal foreign materials is appropriately amplified. In this way, the testing apparatus may more clearly determine whether a processing defect of the secondary battery occurs.

In addition, according to some embodiments of the present disclosure, a secondary battery testing apparatus and a secondary battery testing method, which are suitable for use in a cylindrical electrode assembly, may be provided. In some embodiments, the inner tube may be provided in a cylindrical shape to pressurize the cylindrical electrode assembly while the working fluid is supplied, and thus the testing apparatus may generate an appropriate pressurized state for the cylindrical electrode assembly and perform measurement of the leakage current. In addition, the inner tube provided to be expandable and contractible may relatively easily respond to various specifications of the electrode assembly, thereby contributing to improving usability of the testing apparatus.

In addition, according to some embodiments of the present disclosure, a secondary battery testing apparatus and a secondary battery testing method, which are capable of improving the reliability of test results, may be provided. In some embodiments, the testing apparatus may uniformly pressurize the outer surface of the electrode assembly by the medium of the working fluid, and the leakage current of the electrode assembly may be measured while the uniform pressurizing force is applied to the electrode assembly. Accordingly, whether internal foreign materials are present in the entire area of the electrode assembly may be detected more clearly, and reliability of the test results can be improved.

In addition, according to some embodiments of the present disclosure, a secondary battery testing apparatus and a secondary battery testing method, which are capable of preventing an electrode assembly from being damaged during a testing process, may be provided. In some embodiments, the testing apparatus may be provided to pressurize the outer surface of the electrode assembly due to the supply of the working fluid while an inner tube of a flexible material is in contact with the outer surface of the electrode assembly. Such a pressurization method may effectively prevent damage to the outer surface of the electrode assembly during the testing process. In addition, the pressurization method may contribute to applying a more uniform pressure to the outer surface of the electrode assembly through a distribution of the working fluid.

In addition, according to some embodiments of the present disclosure, a secondary battery testing apparatus and a secondary battery testing method, which are capable of improving a test speed, may be provided. In some embodiments, the testing apparatus may contribute to improving a test speed by applying pressure to the entire outer surface of the electrode assembly through a single pressurization process after the electrode assembly is input.

In addition, according to some embodiments of the present disclosure, a secondary battery testing apparatus and a secondary battery testing method, which are capable of easily applying various test conditions, may be provided. In some embodiments, the testing apparatus may apply various test conditions to the electrode assembly by changing a flow rate, a pressure, a time, a period, a temperature, a type, etc., of the working fluid. In addition, each of the test conditions may be implemented within a single testing apparatus solely through practically appropriate control of the working fluid.

The content described above is merely an example of applying the principle of the present disclosure, and other configurations may be further included without departing from the scope of the present disclosure.

According to some embodiments of the present disclosure, a secondary battery testing apparatus and a secondary battery testing method can be provided.

In addition, according to some embodiments of the present disclosure, a secondary battery testing apparatus and a secondary battery testing method, which are capable of appropriately determining whether a processing defect of a secondary battery occurs, can be provided.

In addition, according to some embodiments of the present disclosure, a secondary battery testing apparatus and a secondary battery testing method, which are suitable for use in a cylindrical electrode assembly, can be provided.

In addition, according to some embodiments of the present disclosure, a secondary battery testing apparatus and a secondary battery testing method, which are capable of improving the reliability of test results, can be provided.

In addition, according to some embodiments of the present disclosure, a secondary battery testing apparatus and a secondary battery testing method, which are capable of preventing an electrode assembly from being damaged during a testing process, can be provided.

In addition, according to some embodiments of the present disclosure, a secondary battery testing apparatus and a secondary battery testing method, which are capable of improving a test speed, can be provided.

In addition, according to some embodiments of the present disclosure, a secondary battery testing apparatus and a secondary battery testing method, which are capable of easily applying various test conditions, can be provided.

What is claimed is:

1. A secondary battery testing apparatus comprising:
an outer case provided with an opening for receiving an electrode assembly; and
an inner tube provided in a cylindrical shape, disposed inside the outer case, and expanding due to a working fluid supplied to an inner chamber to pressurize an outer surface of the electrode assembly.

2. The secondary battery testing apparatus of claim 1, wherein at least a portion of the outer case is formed of a harder material than the inner tube to support expansion of the inner tube.

3. The secondary battery testing apparatus of claim 1, wherein the opening is provided to receive the electrode assembly in a direction along a central shaft.

4. The secondary battery testing apparatus of claim 1, wherein the inner chamber is provided to extend in a cylindrical shape inside the inner tube.

5. The secondary battery testing apparatus of claim 1, wherein:
the inner tube includes an inner surface extending to surround an accommodation space, in which the electrode assembly is disposed, in a circumferential direction; and
the inner surface comes into contact with and pressurizes the outer surface of the electrode assembly while the working fluid is supplied.

6. The secondary battery testing apparatus of claim 1, wherein the inner tube is provided such that an outer surface of the inner tube expands while supported on an inner surface of the outer case, and an inner surface of the inner tube pressurizes the outer surface of the electrode assembly.

7. The secondary battery testing apparatus of claim 1, wherein a material of the inner tube includes at least one of butyl rubber, ethylene propylene diene monomer (EPDM) rubber, Kevlar, and a polyethylene resin.

8. The secondary battery testing apparatus of claim 1, wherein the inner tube includes an injection hole connected to a supply unit for the working fluid and configured to guide the working fluid to be supplied from the supply unit to the inner chamber.

9. The secondary battery testing apparatus of claim 1, further comprising measurement terminals electrically connected to electrodes of the electrode assembly and configured to apply a test voltage to the electrode assembly in a state in which the electrode assembly is pressurized.

10. The secondary battery testing apparatus of claim 9, wherein the measurement terminals include:
a first measurement terminal electrically connected to a first surface of the electrode assembly through the opening; and
a second measurement terminal disposed inside the outer case and electrically connected to a second surface of the electrode assembly.

11. The secondary battery testing apparatus of claim 9, further comprising a detector configured to measure at least one of a leakage current and an insulation resistance between the measurement terminals while the test voltage is applied.

12. The secondary battery testing apparatus of claim 1, further comprising a stage disposed inside the inner tube to allow the electrode assembly to be seated and provided to be movable in input and discharge directions of the electrode assembly.

13. The secondary battery testing apparatus of claim 12, wherein the stage includes a core pin inserted into and fastened in a winding hole provided in a central shaft of the electrode assembly when the electrode assembly is seated.

14. A secondary battery testing method comprising:
inserting a cylindrical electrode assembly into an accommodation space inside an inner tube;
supplying a working fluid to the inner tube and pressurizing an outer surface of the electrode assembly by an inner surface of the inner tube; and
applying a test voltage to each electrode of the electrode assembly and measuring at least one of a leakage current and an insulation resistance between measurement terminals while the test voltage is applied.

15. The secondary battery testing method of claim 14, further comprising:
discharging at least a portion of the working fluid from the inner tube and releasing a pressure applied to the outer surface of the electrode assembly; and
separating the electrode assembly from the inner tube.
